(19) United States
(12) Patent Application Publication
(10) Pub. No.: US 2015/0085504 A1
(43) Pub. Date: Mar. 26, 2015

(54) Systems and Methods for Improving Service Life of Circuit Boards

(71) Applicant: Ellis W. Patrick, Sharpsburg, GA (US)

(72) Inventor: Ellis W. Patrick, Sharpsburg, GA (US)

(21) Appl. No.: 14/493,419

(22) Filed: Sep. 23, 2014

Related U.S. Application Data
(60) Provisional application No. 61/881,871, filed on Sep. 24, 2013.

(51) Int. Cl. H05K 1/02; H05K 3/10; H05K 3/30; H05K 1/03; F21K 99/00

(52) U.S. Cl. CPC H05K 1/0271; H05K 1/028; H05K 1/0296; H05K 1/0393; F21K 9/30; F21K 9/90; H05K 3/305; H05K 3/10; F21Y 2101/02
USPC 362/382; 174/250; 174/251; 29/829; 29/846; 29/840

(57) ABSTRACT

In one aspect, a circuit board includes a base board and a layer of an elastic material comprising a first surface and a second surface. The layer of elastic material is adhered to the base board via the first surface. The circuit board further includes an electrical trace disposed on the second surface of the layer of elastic material. At least a portion of the layer of elastic material stretches or shrinks when the base board expands or contracts. A method of manufacturing a circuit includes obtaining an aluminum board, obtaining a layer of an elastic material, and applying a layer of adhering material to a surface of the aluminum board. The method further includes disposing the layer of the elastic material onto the layer of adhering material, and adhering the layer of the elastic material onto the aluminum board via the layer of adhering material.

### RELATED APPLICATIONS

The present application claims priority under 35 U.S.C. §119(e) to and incorporates herein by reference U.S. Provisional Patent Application No. 61/881,871, filed on Sep. 24, 2013, and titled “Systems and Methods For Improving Service Life of LED Boards.”

### TECHNICAL FIELD

The present disclosure relates to printed circuit boards. Specifically, the present disclosure relates to a circuit board with reduced stress on solder joints and improved service life.

### BACKGROUND

Printed circuit boards (PCBs) include a layer of electrical traces which make up the desired circuit connections. The electrical traces typically include a plurality of solder pads or connection points to which respective electrical components are to be soldered, thereby electrically coupling the electrical components in the desired circuit layout. The solder pads, along with the electrical traces, are typically printed onto a base board such that the solder pads for a specific component are spaced apart and dimensioned in accordance with the spacing and dimensions of the contacts of the specific electrical component.

Typically, circuit boards used with surface mount light emitting diodes (LEDs) comprise an aluminum core board with a dielectric layer on which the electrical traces are printed. The LEDs are surface mounted onto the circuit board via an anode contact and a cathode contact. However, the aluminum core board has a greater coefficient of thermal expansion than does the LED package. Thus, as heat is applied to the circuit board, the distance between the anode and cathode contacts of the LED does not expand as much as the aluminum expands. Eventually, this may lead to solder cracking at the solder joints between the contacts and the circuit board, resulting in board failure.

### SUMMARY

Generally, in one aspect of the present disclosure, a circuit board includes a base board and a layer of an elastic material comprising a first surface and a second surface. The layer of elastic material is adhered to the base board via the first surface. The circuit board further includes an electrical trace disposed on the second surface of the layer of elastic material. At least a portion of the layer of elastic material stretches or shrinks when the base board expands or contracts.

In another aspect of the present disclosure, a method of manufacturing a circuit includes obtaining an aluminum board, obtaining a layer of an elastic material, and applying a layer of adhering material to a surface of the aluminum board. The method further includes disposing the layer of the elastic material onto the layer of adhering material, and adhering the layer of the elastic material onto the aluminum board via the layer of adhering material.

In another aspect of the present disclosure, a method of manufacturing a printed circuit board includes obtaining a base circuit board. The base circuit board comprises an aluminum board and a layer of elastic material disposed on a surface of the aluminum board. The method further includes disposing one or more electrical traces onto the base circuit board, wherein the one or more electrical traces experience less expansion per unit surface area than the base circuit board.

### BRIEF DESCRIPTION OF THE DRAWINGS

Reference will now be made to the accompanying drawings, which are not necessarily drawn to scale, and wherein:

FIG. 1 is a cross-sectional representation of a circuit board with improved service life, in accordance with example embodiments of the present disclosure;

FIG. 2 is a top view of a circuit board with improved service life, in accordance with example embodiments of the present disclosure;

FIG. 3 is a perspective view of the circuit board of FIG. 2 and an optics assembly, in accordance with example embodiments of the present disclosure;

FIG. 4 is a top view of a light module containing the circuit board and optics assembly of FIG. 3, in accordance with example embodiments of the present disclosure;

FIG. 5 is a flow diagram of a method of manufacturing a base board for a circuit board with improved service life, in accordance with example embodiments of the present disclosure; and

FIG. 6 is a flow diagram of a method of manufacturing a circuit board with improved service life, in accordance with example embodiments of the present disclosure.

The drawings illustrate only example embodiments of the disclosure and are therefore not to be considered limiting of its scope, as the disclosure may admit to other equally effective embodiments. The elements and features shown in the drawings are not necessarily to scale, emphasis instead being placed upon clearly illustrating the principles of the example embodiments. In the drawings, reference numerals designate like or corresponding, but not necessarily identical, elements.

### DETAILED DESCRIPTION OF EXAMPLE EMBODIMENTS

Example embodiments disclosed herein are directed to systems and methods for improving the service life of LED circuit boards. Specifically, the example embodiments provide the ability to relieve stress on the solder joints of LEDs and other onboard components caused by thermal expansion of the circuit board. The integrity of the solder joints is better maintained over time, thereby improving the service life of the LED circuit board. The example embodiments make reference to LEDs as an example component on a circuit board. However, the principles and techniques provided in this disclosure apply to any surface mount electrical component that is soldered to a circuit board.

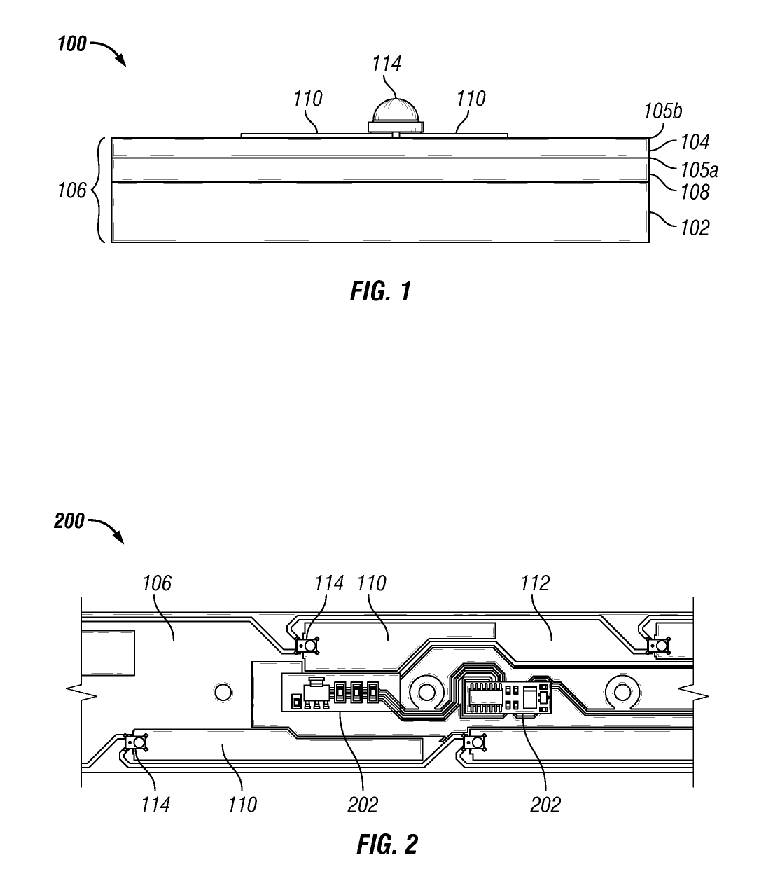

FIG. 1 illustrates a cross-sectional view of a circuit board with improved service life, in accordance with an example embodiment of the present disclosure. FIG. 2 illustrates a top view of a printed circuit board assembly 200 using the circuit board of FIG. 1, in accordance with example embodiments of the present disclosure. Referring first to FIG. 1, in certain example embodiments, the circuit board 100 includes an aluminum board 102 and a layer of polyimide material 104 or alternative elastic material. The aluminum board 102 and the layer of polyimide 104 make up a base board 106. In certain example embodiments, the polyimide 104 is adhered to the aluminum board 102 via a tape 108. The tape 108 has certain appropriate qualities, such as being double-sided, thereby adhering between and to both the polyimide 104 and the aluminum board 102. The tape 108 is also chosen to be able to withstand the high temperatures of a reflow oven such that when the circuit board 100 is subject to reflow soldering, the integrity of the tape 108 is maintained. Additionally, in certain example embodiments, the tape 108 is pressure-sensitive. In certain example embodiments, the polyimide material 104 is replaced by another elastic material.

Referring now to FIGS. 1 and 2, in certain example embodiments, the circuit board 100 further comprises an electrical or electrical trace 110 disposed on the polyimide 104 opposite the aluminum board 102. Alternatively stated, the layer of polyimide 104 includes a first side 105a and a second side 105b, in which the first side 105a of the polyimide 104 is adhered to the aluminum board 102 by the tape 108 and the electrical trace 110 is laid on the second side 105b of the elastic material 104. In certain example embodiments, the electrical trace 110 is fabricated from 2 oz. copper. In certain example embodiments, one or more LEDs 114 and other electrical components 202 are soldered onto one or more areas of the electrical trace 110. Specifically, in certain example embodiments, the electrical trace 110 includes one or more solder pads for receiving and coupling to the LEDs 114 or electrical components 202. In certain example embodiments, a solder mask 112 or dielectric is applied over the electrical trace 110. The solder mask 112 makes the underlying electrical trace 110 more resistant to oxidation and helps prevent accidental electrical contact or shorting of the trace 110.

The aluminum board 102 typically exhibits greater thermal expansion than does the electrical trace 110 and the electrical connections. However, the polyimide layer 104 has a high modulus of elasticity and acts as a buffer between the aluminum board 102 and the electrical traces 110. Specifically, as the aluminum board 102 expands, certain portions of the polyimide layer 104 stretch accordingly. However, the portions of the polyimide layer 104 which are directly coupled to the electrical traces 110 are able to remain relatively stable. Thus, the stretching force and stress that would otherwise be felt by the electrical connections caused by disproportionally large expansion of the aluminum board 102 is largely assumed by the polyimide layer 104. Accordingly stress on the electrical connections is reduced and the printed circuit board assembly 200 is more resilient and robust against fluctuating temperatures. As a result, the printed circuit board assembly 200 is more reliable and has an increased operational lifetime.

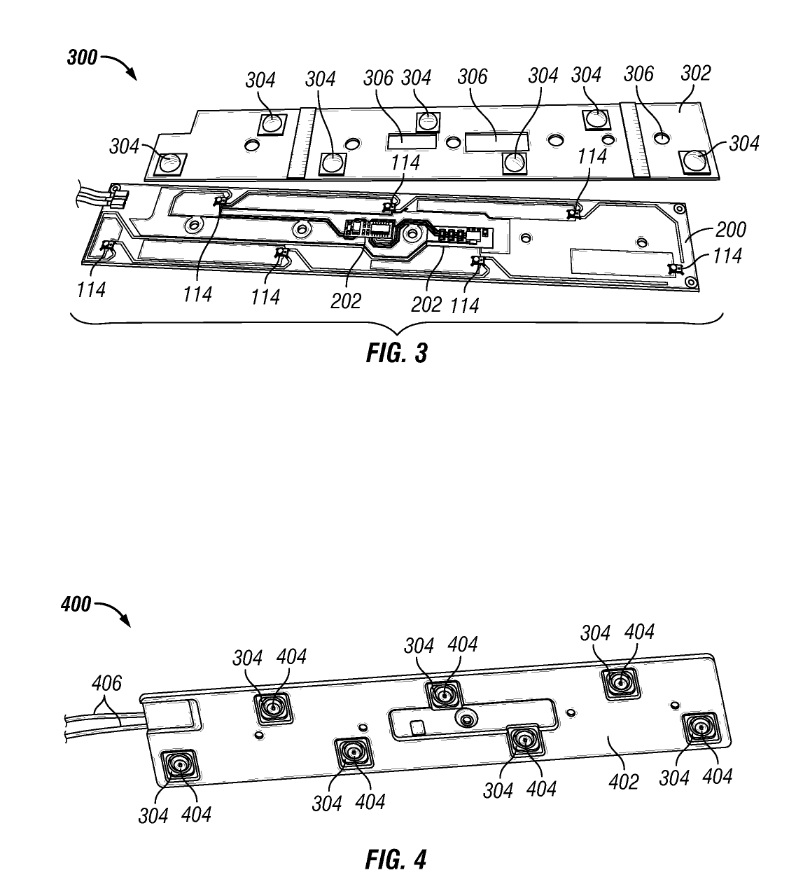

FIG. 3 illustrates the printed circuit board assembly 200 of FIG. 2 and an optics assembly 300. In certain example embodiments, the optics assembly 300 includes a plurality of LED optics 304 disposed on a high-density polyethylene substrate 302, such as Tyvek®, a registered trademark of DuPont. In certain example embodiments, the substrate includes a plurality of openings 306 formed therein. In certain example embodiments, the substrate 302 includes an adhesive backing through which the substrate 302 can be applied to the printed circuit board assembly 200. The optics 304 are disposed over the LEDs 114 and the openings 306 are disposed around the other components 202 when the optics assembly 300 is applied to the printed circuit board assembly 200.

FIG. 4 illustrates an LED light module 400 in accordance with an example embodiment of the present disclosure. The light module 400 includes a housing 402 which houses the printed circuit board assembly 200 coupled to the optics assembly 300. The housing 402 includes a plurality of openings 404 through which the optics 304 are disposed. The light module 400 further includes a plurality of wires 406 which provide power to the printed circuit board assembly 200 contained therein. The light module 400 of FIG. 4 includes the printed circuit assembly 200 of FIG. 2, which includes a layer of polyimide 104 disposed between the aluminum board 102 and the electrical trace 110. As the polyimide 104 provides a high modulus of elasticity, the effects of thermal expansion of the aluminum board 102 are substantially mitigated by the polyimide 104. Thus, stretching forces and other stresses applied to the electrical traces 110 are decreased. Accordingly, electrical connections between the LEDs 114 and the electrical traces 110 are more secure, making for a more robust and long-lasting light module.

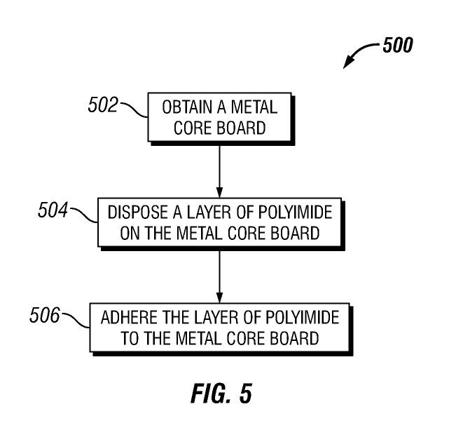

FIG. 5 illustrates a method of manufacturing 500 the base board 106 of the circuit board 100 of FIG. 1, in accordance with example embodiments of the present disclosure. In an example embodiment, the method 500 includes obtaining an aluminum board 102, such as an aluminum core board (step 502). The method further includes disposing a layer of polyimide 104 on a surface of the aluminum board 102 (step 504). In certain example embodiments, a layer of an alternative elastic material is used in place of the polyimide 104. In certain example embodiments, the method 500 includes adhering the polyimide 104 to the aluminum board 102 with a pressure sensitive, double sided, temperature resistant, transfer tape 108, which is able to withstand the high temperatures of the re-flow oven. In certain other example embodiments, the method 500 includes securing the polyimide 104 to the aluminum board 102 using a different technique, agent, or mechanism.

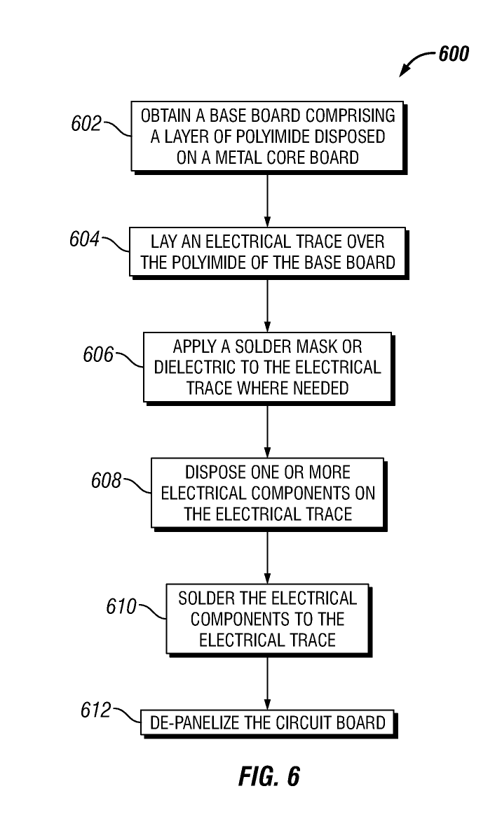

FIG. 6 illustrates a method of manufacturing 600 the circuit board 100 of FIG. 1, in accordance with example embodiments of the present disclosure. In an example embodiment, the method 600 includes obtaining a base board 106 comprising a layer of polyimide 104 disposed on or adhered to an aluminum board 102 (step 602), such as that manufactured through the method 500 of FIG. 5. Alternatively, in another example embodiment, the method 600 of manufacturing the circuit board 100 includes the steps of manufacturing 500 the base board 106 as described in FIG. 5. The method 600 further includes laying an electrical trace 110 on the polyimide 104 of the base board 106 (step 604). In an example embodiments, the electrical trace 110 is created through a subtractive process over the polyimide 104. In another example embodiment, the electrical trace 110 is created through an additive process over the polyimide 104. In certain example processes, the method 600 includes applying a solder mask to the circuit board 100 over the electrical trace 110 (step 606). In certain example embodiments, the method 600 further includes disposing one or more electrical components 114 on the electrical trace 110 (step 608) and soldering the electrical components 114 to the electrical trace 110 (step 610). In an example embodiment, the electrical components 114 are soldered to the electrical trace 110 through a reflow soldering process, which may include running the board with components through a reflow oven. Alternatively, in an example embodiment, the electrical components 114 are soldered to the electrical trace 110 individually. In an example embodiment, the method 600 also includes de-panelizing the circuit board (step 612).

Although the disclosures are described with reference to example embodiments, it should be appreciated by those skilled in the art that various modifications are well within the scope of the disclosure. From the foregoing, it will be appreciated that an embodiment of the present disclosure overcomes the limitations of the prior art. Those skilled in the art will appreciate that the present disclosure is not limited to any specifically discussed application and that the embodiments described herein are illustrative and not restrictive. From the description of the example embodiments, equivalents of the elements shown therein will suggest themselves to those skilled in the art, and ways of constructing other embodiments of the present disclosure will suggest themselves to practitioners of the art. Therefore, the scope of the present disclosure is not limited herein.

What is claimed is:

1. A circuit board, comprising:
a base board;
a layer of an elastic material comprising a first surface and a second surface, wherein the layer of elastic material is adhered to the base board via the first surface; and
one or more electrical traces disposed on the second surface of the layer of elastic material,
wherein at least a portion of the layer of elastic material stretches or shrinks when the base board expands or contracts.

2. The circuit board of claim 1, wherein the elastic material comprises a polyimide material.

3. The circuit board of claim 1, further comprising:
at least one light emitting diode (LED) soldered to the one or more electrical traces.

4. The circuit board of claim 1, wherein at least a portion of the base board comprises aluminum.

5. The circuit board of claim 1, wherein at the layer of elastic material is adhered to the base board via a double-sided transfer tape.

6. The circuit board of claim 5, wherein the transfer tape is resistant to the high-temperatures of a reflow oven.

7. The circuit board of claim 1, wherein the electrical trace experiences less expansion per unit surface area than does the base board when the circuit board expands.

8. The circuit board of claim 1, further comprising:
a layer of dielectric material applied over the one or more electrical traces and base board.

9. A method of manufacturing a circuit board, comprising;
obtaining an aluminum board;
obtaining a layer of an elastic material;
applying a layer of adhering material to a surface of the aluminum board;
disposing the layer of the elastic material onto the layer of adhering material; and
adhering the layer of the elastic material onto the aluminum board via the layer of adhering material.

10. The method of manufacturing a circuit board of claim 9, wherein the elastic material is polyimide.

11. The method of manufacturing a circuit board of claim 9, wherein the layer of adhering material includes a double-sided transfer tape.

12. The method of manufacturing a circuit board of claim 9, further comprising:
disposing one or more electrical traces on a side of the elastic material that is opposite a side to which the aluminum board is adhered, wherein the one or more electrical traces experience less expansion per unit surface area than the aluminum board.

13. The method of manufacturing a circuit board of claim 12, further comprising:
applying a solder mask or a layer of dielectric material over the one or more electrical traces and the aluminum board.

14. The method of manufacturing a circuit board of claim 9, wherein at least a portion of the layer of elastic material stretches or shrinks when the base board expands or contracts.

15. The method of manufacturing a circuit board of claim 12, further comprising:
disposing one or more electronic components on the one or more electrical traces; and
soldering the one or more electronic components onto the one or more electrical traces.

16. A method of manufacturing a printed circuit board, comprising:
obtaining a base circuit board, wherein the base circuit board comprises a aluminum board and a layer of elastic material disposed on a surface of the aluminum board; and
disposing one or more electrical traces onto the base circuit board, wherein the one or more electrical traces experience less expansion per unit surface area than the base circuit board.

17. The method of manufacturing a printed circuit board of claim 16, further comprising:
disposing one or more electronic components on the one or more electrical traces; and
soldering the one or more electronic components onto the one or more electrical traces.

18. The method of manufacturing a printed circuit board of claim 17, further comprising:
reflow soldering the one or more electronic components to the one or more electrical traces.

19. The method of manufacturing the printed circuit board of claim 16, further comprising:
applying a solder mask or a layer of dielectric material to the one or more electrical traces.

20. The method of manufacturing a printed circuit board of claim 16, wherein at least a portion of the layer of elastic material stretches or shrinks when the base board expands or contracts.
